(19) United States
(12) Patent Application Publication
(10) Pub. No.: US 2026/0291512 A1
(43) Pub. Date: Sep. 24, 2026

(54) IN-SITU METASTABILITY-CAUSED ERROR CORRECTION CIRCUIT OF SUCCESSIVE APPROXIMATION ANALOG-TO-DIGITAL CONVERTER

(71) Applicant: SHANGHAI JIAO TONG UNIVERSITY, Shanghai (CN)

(72) Inventors: Jing Jin, Shanghai (CN); Yuekang Guo, Shanghai (CN); Meng Xu, Shanghai (CN); Xiaoming Liu, Shanghai (CN); Linsheng Wu, Shanghai (CN); Jianjun Zhou, Shanghai (CN)

(73) Assignee: SHANGHAI JIAO TONG UNIVERSITY, Shanghai (CN)

(21) Appl. No.: 19/458,725

(22) Filed: Jan. 24, 2026

(30) Foreign Application Priority Data
Mar. 24, 2025 (CN) 202510345768.0

(51) Int. Cl. H03M 1/06

(52) U.S. Cl. CPC H03M 1/0604

(57) ABSTRACT

An in-situ metastability-caused error correction circuit of a successive approximation analog-to-digital converter comprises a NOR gate and a NAND gate which form an error correction module, and a NOR gate, a trigger and a delay unit which form an error detection module, wherein the logic input ends of the NOR gate and the NAND gate of the error correction module are connected with the output end of a comparator of the analog-to-digital converter to be detected, and the logic output ends of the NOR gate and the NAND gate are respectively output to the NOR gate of the error detection module .

### CROSS-REFERENCE TO RELATED APPLICATIONS

This application claims priority to Chinese Patent Application Ser. No. number CN202510345768.0 filed on 24 Mar. 2025.

### TECHNICAL FIELD

The invention relates to a technology in the field of analog-to-digital conversion, in particular to an in-situ metastability-caused error correction circuit of a successive approximation analog-to-digital converter.

### BACKGROUND ART

Metastability refers to the phenomenon that the output of a circuit may fluctuate between two logic levels and cannot determine its final output state within a certain period of time during the conversion process. When the input of the comparator is close to its decision threshold, the output may be unstable between high and low states, resulting in uncertainty. Errors caused by metastability are difficult to calibrate like other errors in the ADC transfer function, which may cause output errors and performance degradation. Existing methods can only detect metastability or correct errors caused by metastability through additional back-end encoding logic in synchronous ADCs.

### SUMMARY OF THE INVENTION

Aiming at the problems that the existing analog-to-digital converter cannot directly correct the bit where the metastability error occurs, cannot determine which bit the metastability error occurs in a SAR cycle, and cannot determine whether the residual error at the end of the SAR is less than an acceptable range, resulting in the easy occurrence of potential conversion errors, the present invention proposes an in-situ metastability-caused error correction circuit for a successive approximation analog-to-digital converter, which performs in-situ correction on the error caused by the metastability of the comparator, can determine that the error is less than the acceptable range, and no error will occur by forced setting, thereby significantly improving the reliability of the ADC and ensuring that it can still maintain high accuracy and stability under variable input conditions.

The present invention is achieved through the following technical solutions:

The invention relates to an in-situ metastability-caused error correction circuit of a successive approximation analog-to-digital converter, comprising: a NOR gate and a NAND gate constituting an error correction module, a NOR gate, a trigger and a delay unit constituting an error detection module, wherein: the logic input ends of the NOR gate and the NAND gate of the error correction module are connected to the output end of the comparator of the analog-to-digital converter to be tested, the logic output ends of the NOR gate and the NAND gate are respectively output to the NOR gate of the error detection module to obtain a decision signal of whether a metastability occurs, the trigger generates an error pre-calibration signal according to the decision signal and the clock signal of the comparator of the analog-to-digital converter to be tested, and the delay unit generates a pair of mutually inverted error correction signals according to the decision signal and the error pre-calibration signal of the trigger and outputs them to the NOR gate and the NAND gate of the error correction module to generate a corrected signal and then outputs it to a latch.

### Technical Effects

The present invention generates a fixed detection time window through a comparator clock and a delay unit, and uses an error correction signal generated by the delay unit to force the NOR gate and NAND gate outputs of the error correction module to generate an output result and skip the comparison process of this data bit, so that the asynchronous successive approximation logic continues. Compared with the prior art, the present invention can effectively eliminate errors caused by metastability. If the metastability does not occur, the correction process will not affect the normal SAR operation, thereby ensuring the reliability and stability of the system in high-speed and high-precision applications.

### BRIEF DESCRIPTION OF THE DRAWINGS

FIG. 1 is a schematic diagram of a circuit of the present invention;

FIG. 2 is a timing diagram of FIG. 1.

### DETAILED DESCRIPTION

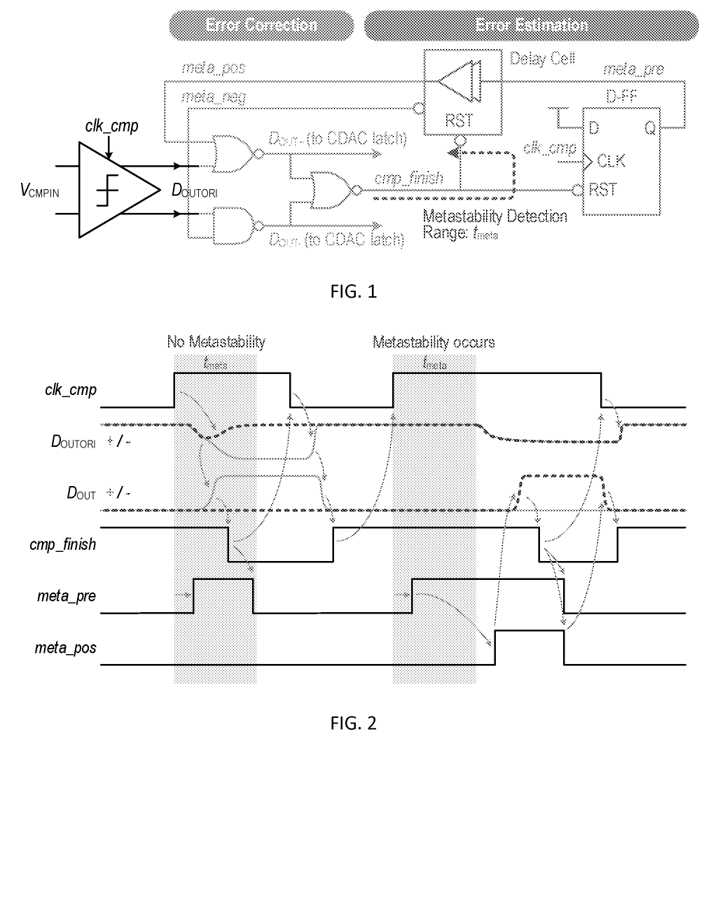

As shown in FIG. 1, the present embodiment relates to an in-situ metastability-caused error correction circuit of a successive approximation analog-to-digital converter, comprising: a NOR gate and a NAND gate constituting an error correction module, a NOR gate, a D flip-flop and a delay unit constituting an error detection module, wherein: the logic input ends of the NOR gate and the NAND gate of the error correction module are connected to the output end of the comparator of the analog-to-digital converter to be tested, the logic output ends of the NOR gate and the NAND gate are respectively output to the NOR gate of the error detection module to obtain a decision signal cmp_finish indicating whether a metastability occurs, the clock signal clk_cmp of the comparator of the analog-to-digital converter to be tested is used as the clock signal of the D flip-flop. The decision signal cmp_finish is used as the reset signal of the D flip-flop, the positive power supply is used as the D input signal of the D flip-flop, the output terminal Q of the D flip-flop outputs the error pre-calibration signal meta_pre, the delay unit generates opposite error correction signals meta_pos and meta_neg according to the error pre-calibration signal meta_pre and the decision signal cmp_finish, the error correction signal meta_pos and the comparator output D_{OUTORI} are passed through the NOR gate to generate the corrected signal D_{OUT+} which is output to the latch of CDAC, the error correction signal meta_neg and the comparator output D_{OUTORI} are passed through the NAND gate to generate the corrected signal D_{OUT-} which is output to the latch of CDAC.

When the decision signal cmp_finish is low, the error pre-calibration signal meta_pre is reset to 0. When the decision signal cmp_finish is high, the error pre-calibration signal meta_pre will become 1 when the first clk_cmp rising edge arrives.

When the decision signal cmp_finish is low, the error correction signal meta_pos is reset to 0 and meta_neg is reset to 1; when the decision signal cmp_finish is high, the error correction signal meta_pos is a delayed signal of the error pre-calibration signal meta_pre.

The initial state of the clock signal clk_cmp is 0, the initial state of the comparator output D_{OUTORI} is 1/1, the initial state of the decision signal cmp_finish is 1, and the initial states of the error correction signals meta_pos and meta_neg are 0 and 1 respectively.

The ratio of NMOS and PMOS transistors in the comparator output stage needs to be set so that the driving capability of PMOS is stronger than that of NMOS, ensuring that the comparator output D_{OUTORI} is more inclined to be pulled to a high level, thereby avoiding the comparator output D_{OUTORI} from being in a 0/0 state during the operation of the comparator.

As shown in FIG. 2, it is the timing of the in-situ correction technology for errors caused by metastability. When the comparator clock clk_cmp rises, the comparator starts to compare, and the D flip-flop in the error detection module is also triggered, and the output flips from 0 to 1. This signal is transmitted through the delay unit. The time range of metastable detection is tₘₑₜₐ. When the comparator is metastable, that is, no clear output result is generated within tₘₑₜₐ, the judgment signal cmp_finish is always high, and the delay unit is not reset. The positive phase error correction signal meta_pos is pulled high, forcing the NOR gate output D_{OUT+} to 0; the negative phase error correction signal meta_neg is pulled low, forcing the NAND gate output D_{OUT-} to 1. Therefore, cmp_finish becomes 0, the D flip-flop and delay unit are reset, meta_pos becomes 0 again, meta_neg becomes 1 again, and waits for the comparison of the next cycle. These operations effectively eliminate the metastability-caused error.

When the comparator does not experience metastable state, that is, a clear output result is generated within the metastable detection time tₘₑₜₐ, the decision signal cmp_finish will become 0, resetting the D flip-flop and delay unit, meta_pos will remain at 1, and meta_neg will remain at 0, which will not affect the normal SAR operation.

After specific actual experiments, the output results of the ADC are repeatedly tested for 2²⁷ data points continuously, and there is no obvious deterioration in the spectrum performance, that is, there is no metastable problem, which can prove that the overall reliability of the ADC is high. In summary, the present invention can perform real-time correction when the ADC is working normally, can handle metastability-caused errors in real time, improve the overall reliability of the system, and ensure the output stability of the ADC under different working conditions. The present invention can effectively eliminate the uncertainty caused by metastability through simple logical assignment operations without the need for complex back-end coding logic, and this simplification makes the design more efficient.

The above-mentioned specific implementation can be partially adjusted in different ways by those skilled in the art without departing from the principle and purpose of the present invention. The protection scope of the present invention shall be based on the claims and shall not be limited by the above-mentioned specific implementation. Each implementation scheme within its scope shall be subject to the constraints of the present invention.

What is claimed is:

1. An in-situ metastability-caused error correction circuit of a successive approximation analog-to-digital converter, characterized in that it comprises: a NOR gate and a NAND gate which form an error correction module, and a NOR gate, a trigger and a delay unit which form an error detection module, wherein the logic input ends of the NOR gate and the NAND gate of the error correction module are connected with the output end of a comparator of the analog-to-digital converter to be detected, and the logic output ends of the NOR gate and the NAND gate are respectively output to the NOR gate of the error detection module so as to obtain a judgment signal for judging whether metastability occurs or not; the trigger generates an error pre-calibration signal according to the judgment signal and a clock signal of a comparator of the analog-to-digital converter to be tested; and the delay unit generates a pair of mutually inverted error correction signals according to the judgment signal and the error pre-calibration signal of the trigger, outputs the error correction signals to the NOR gate and the NAND gate of the error correction module to generate corrected signals, and outputs the corrected signals to the latch.

2. The in-situ metastability-caused error correction circuit of a successive approximation analog-to-digital converter according to claim 1 in which the initial states of the said clock signal, positive phase and negative phase error correction signals are 0 and 1 respectively.

3. The in-situ metastability-caused error correction circuit of a successive approximation analog-to-digital converter according to claim 1 in which the ratio of NMOS and PMOS transistors in the said comparator output stage needs to be set so that the PMOS size is stronger to ensure that the comparator output will not appear in the 0/0 state during the operation of the comparator.

4. The in-situ metastability-caused error correction circuit of a successive approximation analog-to-digital converter according to claim 1 in which the said trigger is a D flip-flop.

5. A method for calibrating the in-situ metastability-caused error correction circuit of a successive approximation analog-to-digital converter according to claim 1, characterized in that: when the comparator clock rising edge arrives, the comparator starts to compare, triggers the trigger in the error detection module and the output flips from 0 to 1;
and when the comparator does not produce a clear output result within the time range of metastable detection, that is, a metastability occurs, the decision signal is always at a high level, that is, the delay unit is not reset, the positive error correction signal is pulled high, and the NOR gate output is forced to be pulled to 0; the negative error correction signal is pulled low, and the NAND gate output is forced to be pulled to 1, the decision signal becomes 0, the trigger and the delay unit are reset, the positive error correction signal becomes 0 again, and the negative error correction signal becomes 1 again, waiting for the comparison of the next cycle to eliminate the metastable state.

6. The method according to claim 5 in which when the comparator does not occur metastability, that is, a clear output result is generated within the metastable detection time, the judgment signal will become 0, the trigger and the delay unit will be reset, the positive phase error correction signal will remain at 1, and the negative phase error correction signal will remain at 0.
